(19) United States
(12) Patent Application Publication
(10) Pub. No.: US 2015/0084668 A1
(43) Pub. Date: Mar. 26, 2015

(54) SEMICONDUCTOR DEVICE AND SEMICONDUCTOR SYSTEM INCLUDING THE SAME

(71) Applicant: SK hynix Inc., Gyeonggi-do (KR)

(72) Inventor: Jae Woong YUN, Seoul (KR)

(73) Assignee: SK hynix Inc., Gyeonggi-do (KR)

(21) Appl. No.: 14/096,917

(22) Filed: Dec. 4, 2013

(30) Foreign Application Priority Data
Sep. 23, 2013 (KR) 10-2013-0112651

(51) Int. Cl. G01R 31/26

(52) U.S. Cl. CPC G01R 31/2601
USPC 324/762.05

(57) ABSTRACT

A semiconductor device includes a test control unit suitable for activating an on-die termination signal in response to a control signal activated in a test mode, and a data mask pad suitable for pull-down driving a data mask signal when the on-die termination signal is activated.

### CROSS-REFERENCES TO RELATED APPLICATION

The present application claims priority under 35 U.S.C. §119(a) to Korean application number 10-2013-0112651, filed on Sep. 23, 2013, in the Korean Intellectual Property Office, which is incorporated herein by reference in its entirety.

### BACKGROUND

1. Technical Field

Various exemplary embodiments relate to a semiconductor device and a semiconductor system including the same, and more particularly, to a technology for decreasing the number of connection pins connected to a probe card in a probe test of a semiconductor device.

2. Related Art

A semiconductor memory device has continuously been developed to increase the degree of integration and an operating speed. In order to increase an operating speed, a so-called synchronous memory device capable of operating in synchronization with a clock provided from an outside of a memory chip has been researched.

First suggested is what is called an SDR (single data rate) synchronous memory device, which inputs or outputs one data through one data pin for one cycle of a clock provided from the outside in synchronization with the rising edge of the clock.

However, the SDR synchronous memory device is not sufficient to satisfy the speed of a system, which operates at a high speed. Accordingly, a DDR (double data rate) synchronous memory device has been suggested as a type of processing two data for one cycle of a clock.

In the DDR synchronous memory device, data are inputted or outputted in synchronization with the rising edge and/or the falling edge of a clock, which is inputted from the outside. That is, two data are consecutively processed through each data input/output pin for one cycle of the clock. Therefore, since the DDR synchronous memory device has a bandwidth at least two times wider than the conventional SDR synchronous memory device without increasing the frequency of a clock, a high speed operation may be correspondingly achieved.

A DDR synchronous memory device adopts a multi-bit prefetch scheme in which multiple bits of data are internally processed at a time. The multi-bit prefetch scheme refers to a scheme in which data sequentially inputted are arranged in parallel in synchronization with a data strobe signal and then the multi-bit data arranged in this way are stored at a time in a memory cell array by a write command, which is inputted in synchronization with an external clock signal.

In general a semiconductor memory device such as a DDR SDRAM (double data rate synchronous DRAM) has at least several tens of millions of memory cells for storing data, and the set of such memory cells is referred to as a memory bank.

A semiconductor memory device stores or outputs data in response to a command which is inputted from a chipset. That is to say, when the chipset requests a write operation, the data are inputted through input pads and stored in memory cells. When the chipset requests a read operation, the data stored in memory cells are outputted to an outside through output pads.

The number of memory banks provided in a semiconductor memory device may be changed depending on a circuit design. These days, in order for large capacity of a semiconductor memory device, the number of memory banks is being increased.

A semiconductor memory device has rapidly developed for its high integration, multi-functionality and low power. According to this trend, the degree of integration and the input/output functions of a semiconductor memory device are being diversified. Therefore, the number of pads of a semiconductor memory device, which are connected to an external device, is being increased.

FIG. 1 is a configuration diagram of a conventional semiconductor system.

The conventional semiconductor system includes a tester 10 and a chip 20.

The tester 10 includes ground voltage supply units 11 and 12. The ground voltage supply units 11 and 12 supply a ground voltage to a data mask (DM) pad P1 and a data (DQ) pad P2 of the chip 20.

The tester 10 includes a probe card, which is connected with the data mask pad P1 and the data pad P2 of the chip 20 through connection pins and tests the chip 20. The chip 20 includes the data mask pad P1, the data pad P2, and a termination unit 21.

If a termination enable signal TEN is activated, the termination unit 21 operates, and an on-die termination signal ODTEN is activated to a high level. Then, the connection pin of the data mask pad P1 and the data pad P2 is pulled down in response to the ground voltage applied from the tester 10.

When performing a termination test for a semiconductor memory device on a wafer, in order to increase the efficiency of the termination test, the termination test for the data mask pad P1 and the data pad P2 is omitted. Accordingly, in the test mode, the data mask pad P1 and the data pad P2 are connected to the terminal of a power supply voltage (VDD) or a ground voltage (VSS).

A semiconductor memory device has a plurality of pads or pins and communicates with an external controller through the plurality of pads. While the pads are essential component elements of the semiconductor memory device to communicate with the external controller, they may also be a weakness in miniaturizing a semiconductor memory device. As a semiconductor memory device trends toward large capacity, the number of pads is being increased, and an area occupied by the pads is being correspondingly enlarged.

In particular, as a memory device is developed from a DDR3 specification to a low power DDR4 specification, the number of input/output pins in each bank is increased. In this case, a burden is placed on the fabrication of a probe test card, and the number of pads for testing is increased in a semiconductor memory device.

### SUMMARY

Various exemplary embodiments of the present invention are directed to a semiconductor system capable of decreasing the number of connection pins between a semiconductor device and a probe card in a probe test.

In an embodiment of the present invention, a semiconductor device includes a test control unit suitable for activating an on-die termination signal in response to a control signal activated in a test mode, and a data mask pad suitable for pull-down driving a data mask signal when the on-die termination signal is activated.

The semiconductor device further includes a termination unit suitable for functioning as a termination resistor and generating a termination control signal when a termination enable signal is activated.

The test mode includes a probe test mode.

The data mask pad is grounded when the on-die termination signal is activated.

The test control unit activates the on-die termination signal when at least one of the control signal and the termination control signal is activated.

The semiconductor device further includes a data pad suitable for operating in response to the terminal control signal and grounded in response to a ground voltage applied from an external tester, in the test mode.

The semiconductor device further includes a termination unit configured to perform a function of a termination resistor when a termination enable signal is activated, and provide the termination control signal to the test control unit.

The semiconductor device further includes a control signal generation unit suitable for activating the control signal in the probe test mode.

In another embodiment of the present invention, a semiconductor system include a semiconductor device including first and second pads, and a tester suitable for grounding the first pad by being connected thereto in a test mode, wherein the semiconductor device is suitable for grounding the second pad by activating an on-die termination signal in the test mode.

The semiconductor device further includes a termination unit suitable for functioning as a termination resistor and generating a termination control signal when a termination enable signal is activated.

The test mode includes a probe test mode.

In the tester, a probe is connected with the first pad in the probe test mode.

### BRIEF DESCRIPTION OF THE DRAWINGS

Features, aspects, and embodiments of the present invention are described in conjunction with the attached drawings, in which:

FIG. 1 is a configuration diagram of a conventional semiconductor system;

FIG. 2 is a configuration diagram illustrating a semiconductor system in accordance with an embodiment of the present disclosure;

FIG. 3 is a detailed circuit diagram illustrating a test control unit shown in FIG. 2; and

FIG. 4 is a detailed circuit diagram illustrating a data mask pad shown in FIG. 2.

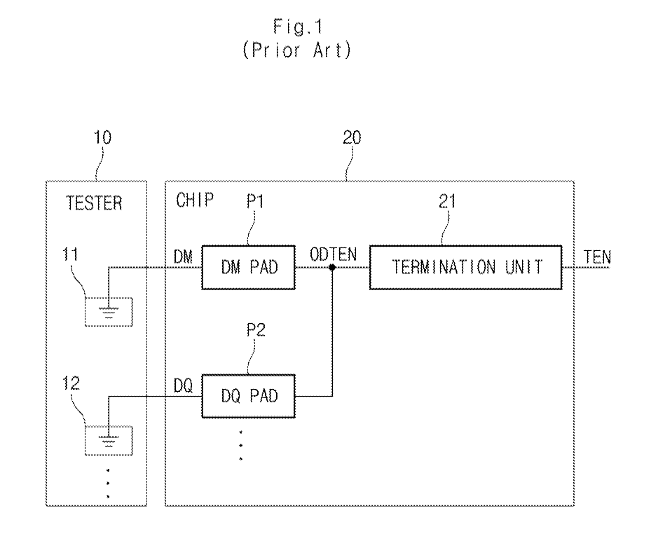

### DETAILED DESCRIPTION

Hereinafter, a semiconductor device and a semiconductor system including the same according to the present invention will be described below with reference to the accompanying drawings through exemplary embodiments. Throughout the disclosure, reference numerals correspond directly to the like numbered parts in the various figures and embodiments of the present invention. It is also noted that in this specification, “connected/coupled” refers to one component not only directly coupling another component but also indirectly coupling another component through an intermediate component. In addition, a singular form may include a plural form as long as it is not specifically mentioned in a sentence.

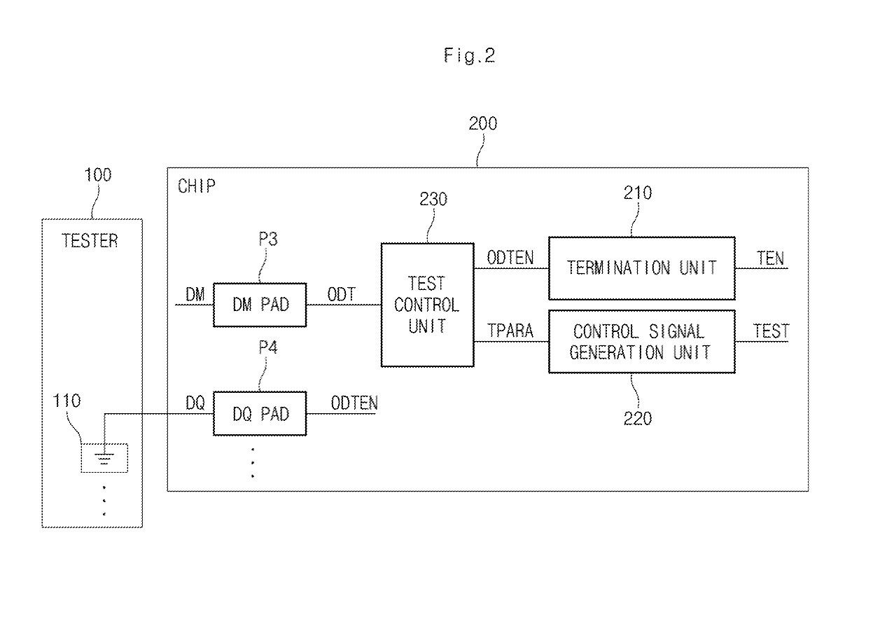

FIG. 2 is a configuration diagram of a semiconductor system in accordance with an embodiment of the present disclosure.

The semiconductor system in accordance with the embodiment of the present disclosure includes a tester 100 and a chip 200.

The tester 100 includes a ground voltage supply unit 110. The ground voltage supply unit 110 is configured to supply a ground voltage to a data (DQ) pad P4 of the chip 200. The tester 100 may include a probe card which is connected with the data pad P4 of the chip 200 and tests the chip 200.

The chip 200 includes a data mask (DM) pad P3, the data pad P4, a termination unit 210, a control signal generation unit 220, and a test control unit 230. The data pad P4 is provided to input and output data DQ to and from a semiconductor memory device. The data mask pad P3 is a pad, which receives a data mask signal DM. The data mask signal DM is a signal, which is used in a write operation of a semiconductor memory device.

The data mask signal DM is used as the data processing capacity and the data processing speed of the semiconductor memory device increase. The data mask signal DM is for masking a specific memory cell at a specific timing when the write operation is performed. In other words, the data mask signal DM is activated to block a portion of the data inputted to the chip 200 through the data pad P4 from being transferred to an internal circuit of the semiconductor memory device when it is not necessary according to a data pattern to change the data stored in the semiconductor memory device.

In particular, since a DDR synchronous memory device has a data mask (DM) pin for masking data that is not required to write, input of data may be blocked when a data mask signal is activated.

The data mask pad P3 may be used for termination data strobe or redundancy data strobe, and to this end, the termination unit 210 is disposed. In order to prevent the occurrence of a timing-related problem due to the fact that the loads of data strobe signals become different in a memory system using semiconductor memory devices with different numbers of data input/output pins, a data mask signal may play the role of a data strobe signal. Also, in order to make loads the same, electrical termination may be provided to the data mask pad P3. This function may be selected through setting of a mode register set (MRS).

In a normal operation of the semiconductor memory device a write command is inputted for the write operation. If the write command is applied, the semiconductor memory device receives input data DQ through the data pad P4 and receives the data mask signal DM through the data mask pad P3.

Input data is masked if the data mask signal DM is enabled, and it is not masked if the data mask signal DM is disabled. Accordingly, the semiconductor memory device receives the input data DQ and the data mask signal DM through respectively allocated pads, generates internal data from the input data DQ, transmits the internal data to a data input/output line, and stores the internal data therein. As can be readily seen, the data mask signal DM is not used in a read operation of the semiconductor memory device.

A semiconductor memory device such as a DRAM (dynamic random access memory) may undergo a testing step at a wafer level and a package level to detect a defect of a circuit. After semiconductor devices are designed on a wafer, selected semiconductor devices (that is, test cells) among the semiconductor devices are tested through test patterns, which are formed in a specific region of the wafer, by the external tester 100. This is referred to as a wafer level test.

As semiconductor designing and processing technologies are developed, a semiconductor device having at least a low power DDR4 specification is widely used. In the case of a DDR DRAM with a high operation frequency, the termination unit 210 is used to prevent distortion of signals in a data transfer process.

Termination technologies include an on-die termination (ODT) technology in which the termination unit 210 is disposed in a semiconductor memory device. The on-die termination technology is widely used because it has high signal integrity. The termination unit 210 is an impedance matching circuit which is also referred to as an on-chip termination circuit, and it is disposed adjacent to the pads P3 and P4 in the chip 200.

The on-die termination circuit of the termination unit 210 is turned off and does not operate in the read operation. In the write operation, the on-die termination circuit of the termination unit 210 is turned on in response to a termination enable signal TEN and performs the function of a termination resistor. As the operating speed of a semiconductor memory device increases, it becomes necessary to test the operation of an on-die termination circuit.

In a wafer level test, the probe of the tester 100 may be brought into direct contact with pads for testing internal voltages. For such a semiconductor device, an open test and a short/leakage test may be performed.

The main purpose of the open test is to check whether the connection state between the external tester 100 and the semiconductor chip 200 is proper or not. In a wafer state, the connection state between the data pad P4 of the semiconductor chip 200 and the probe card is checked. In the open test, all input/output pads/pins of the semiconductor chip 200 are grounded, and bias current is applied to a pad/pip to be tested. Namely, the ground voltage is applied from the ground voltage supply unit 110 of the tester 100 to the data pad P4 of the semiconductor chip 200.

Thereafter, the external tester 100 measures the voltage of the input/output pad/pin, and determines whether the measured voltage is within a reference range. If the measured voltage is within the reference range, it is determined that contact is normal, and, if the measured voltage is not within the reference range, it is determined that a short circuit or an open circuit occurs.

In the embodiment of the present disclosure, the ground voltage applied from the tester 100 is applied to only the data pad P4 of the chip 200, and it is not applied to the data mask pad P3. In the probe test mode of the chip 200, the data mask pad P3 becomes internally a grounded state in response to an on-die termination signal ODT. While the data pad P4 is grounded by the tester 100, the data mask pad P3 is internally grounded by activating the on-die termination signal ODT.

That is to say, because the data mask pad P3 is not in contact with the probe of the tester 100 in the test operation, the data mask pad P3 is not applied with the ground voltage through a connection pin from the tester 100. According to this fact, the chip 200 according to the embodiment of the present disclosure allows the number of pins allocated to the probe card of the tester 100 to be decreased.

For example, in view of the structure of the semiconductor device with the LPDDR4 specification, data of byte units are separately processed. Accordingly, data mask pads P3 are separated for the respective byte units of data. In this case, in the probe test, respective data mask pins may be controlled to the level of the ground voltage. For example, 4 data mask pins may be allocated to the probe card of the tester 100. In the embodiment of the present disclosure, since the tester 100 and the data mask pins of the chip 200 are not in contact with each other as described above, 4 data mask pins allocated to the probe card may be decreased.

In detail, if the termination enable signal TEN is activated, the termination unit 210 operates to perform the function of a termination resistor and activates a termination control signal ODTEN. In the probe test mode, if a test signal TEST is activated, the control signal generation unit 220 activates a control signal TPARA and outputs the activated control signal TPARA to the test control unit 230. The test signal TEST may be generated using MRS (mode register set) codes. The control signal TPARA is a signal, which allows the probe test to be internally recognized when performing the probe test.

The test control unit 230 combines the termination control signal ODTEN and the control signal TPARA and activates the on-die termination signal ODT. In the case where the on-die termination signal ODT is activated, the data mask pad P3 recognizes the corresponding situation as a test mode and controls the data mask signal DM to be a ground voltage state.

If the termination control signal ODTEN is activated in the termination test, the data pad P4 is applied with the ground voltage from the external tester 100 to omit the termination test. The data pad P4 is connected to the probe of the tester 100 in a test operation and is provided with the electrical termination of the termination unit 210.

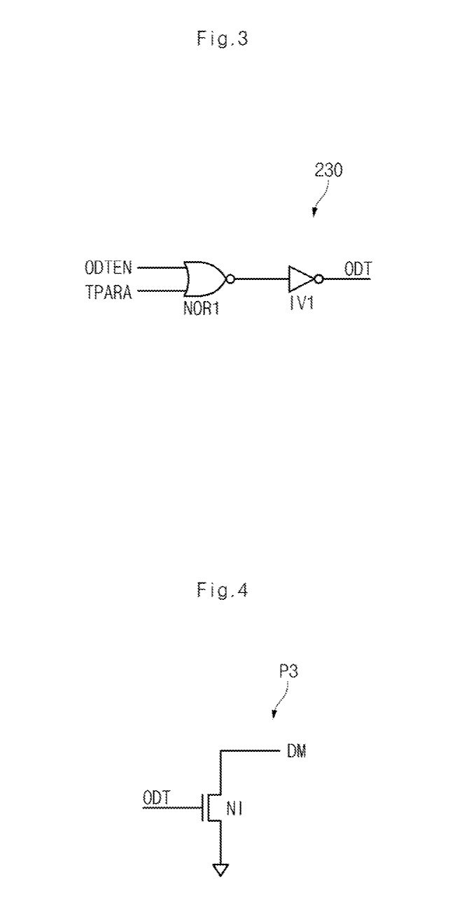

FIG. 3 is a detailed circuit diagram of the test control unit 230 shown in FIG. 2.

The test control unit 230 includes a NOR gate NOR1 and an inverter IV1. The NOR gate NOR1 performs a NOR operation on the terminal control signal ODTEN and the control signal TPARA. The inverter IV1 inverts the output of the NOR gate NOR1 and outputs the on-die termination signal ODT.

The test control unit 230 having such a configuration outputs the on-die termination signal ODT to a logic high level in the case where at least one signal of the termination control signal ODTEN and the control signal TPARA is activated. That is to say, the on-die termination signal ODT may be activated to the high level in the test mode when the control signal TPARA is a high level even in the case where the termination control signal ODTEN is a low level.

FIG. 4 is a detailed circuit diagram of the data mask pad P3 shown in FIG. 2.

The data mask pad P3 includes an NMOS transistor N1 as a pull-down driving element. The NMOS transistor N1 is connected between the application terminal of the data mask signal DM and the ground voltage terminal, and is applied with the on-die termination signal ODT through the gate terminal thereof.

In the data mask pad P3 having such a configuration, the NMOS transistor N1 is turned on when the on-die termination signal ODT is activated to the high level, and the data mask signal DM is driven to the level of the ground voltage. Conversely, when the on-die termination signal ODT is a low level, the data mask signal DM becomes a floating state.

As is apparent from the above descriptions, according to the embodiment of the present invention, the number of data mask pins connected with a probe card may be decreased when performing a probe test in the LPDDR4 specification of a semiconductor device.

So far, an embodiment of the present invention has been described in detail. For reference, embodiments including additional component elements, which are not directly associated with the technical spirit of the present invention, may be exemplified in order to describe the present invention in further detail.

Moreover, activation, deactivation, high configuration and low configuration for indicating the enabled states of signals and circuits may be changed depending upon an embodiment. Furthermore, the configurations of transistors may be changed as the occasion demands to realize even the same functions. That is to say, the configurations of a PMOS transistor and an NMOS transistor may be replaced with each other, and as the occasion demands, various transistors may be employed. Since these circuit changes have a large number of cases and can be easily inferred by those skilled in the art, the enumeration thereof will be omitted herein.

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a test control unit suitable for activating an on-die termination sign in response to a control signal activated in a test mode; and
a data mask pad suitable for pull-down driving a data mask signal when the on-die termination signal is activated.

2. The semiconductor device according to claim 1, further comprising:
a termination unit suitable for functioning as a termination resistor and generating a termination control signal when a termination enable signal is activated.

3. The semiconductor device according to claim 1, wherein the test mode comprises a probe test mode.

4. The semiconductor device according to claim 1, wherein the data mask pad is grounded when the on-die termination signal is activated.

5. The semiconductor device according to claim 2, wherein the test control unit activates the on-die termination signal when at least one of the control signal and the termination control signal is activated.

6. The semiconductor device according to claim 5, wherein the test control unit comprises:
a NOR gate suitable for performing a NOR operation on the control signal and the termination control signal; and
an inverter suitable for inverting an output of the NOR gate and output the on-die termination signal.

7. The semiconductor device according to claim 1, wherein the data mask pad comprises a transistor connected between an application terminal of the data mask signal and a ground voltage terminal and applied with the on-die termination signal through a gate terminal thereof.

8. The semiconductor device according to claim 7, wherein the transistor comprises an NMOS transistor.

9. The semiconductor device according to claim 2, further comprising:
a data pad suitable for operating in response to the terminal control signal and grounded in response to a ground voltage applied from an external tester, in the test mode.

10. The semiconductor device according to claim 3, further comprising:
a control signal generation unit suitable for activating the control signal in the probe test mode.

11. A semiconductor system comprising:
a semiconductor device including first and second pads; and
a tester suitable for grounding the first pad by being connected thereto in a test mode,
wherein the semiconductor device is suitable for grounding the second pad by activating an on-die termination signal in the test mode.

12. The semiconductor device according to claim 11, wherein the semiconductor device further includes:
a termination unit suitable for functioning as a termination resistor and generating a termination control signal when a termination enable signal is activated.

13. The semiconductor system according to claim 12, wherein the semiconductor device further includes:
a test control unit suitable for activating the on-die termination signal when at least one of a control signal activated in the test mode and the termination control signal is activated.

14. The semiconductor system according to claim 13, wherein the test control unit comprises:
a NOR gate configured to NOR the control signal and the termination control signal; and
an inverter configured to invert an output of the NOR gate and output the on-die termination signal.

15. The semiconductor system according to claim 11, wherein the test mode comprises a probe test mode.

16. The semiconductor system according to claim 15, wherein, in the tester, a probe is connected with the first pad in the probe test mode.

17. The semiconductor system according to claim 11, wherein the first and second pad comprises data and data mask pads, respectively.

18. The semiconductor system according to claim 17, wherein the data mask pad pull-down drives a data mask signal to a ground voltage level when the on-die termination signal is activated.

19. The semiconductor system according to claim 11, wherein the first and second pad comprises a transistor which is connected between an application terminal of the data mask signal and a ground voltage terminal and is applied with the on-die termination signal through a gate terminal thereof.

20. The semiconductor system according to claim 19, wherein the transistor comprises an NMOS transistor.
